(19) United States
(12) Patent Application Publication
(10) Pub. No.: US 2008/0067516 A1
(43) Pub. Date: Mar. 20, 2008

(54) Method for manufacturing a TFT transistor

(75) Inventor: Claudia Caligiore, Giarre (CT) (IT)

Correspondence Address: Bryan A. Santarelli;GRAYBEAL JACKSON HALEY LLP, Suite 350, 155-108th Avenue NE, Bellevue, WA, 98004-5973, US

(73) Assignee: STMicroelectronics S.r.l.

(21) Appl. No.: 11/890,031

(22) Filed: Aug. 2, 2007

(30) Foreign Application Priority Data
Aug. 2, 2006 (IT) MI2006A 001541

(51) Int. Cl. H01L 29/04; H01L 21/336

(52) U.S. Cl. 257/66; 438/166; 257/E29.003; 257/E21.413

(57) ABSTRACT

An embodiment of a process for manufacturing a TFT transistor on a substrate comprising the steps of: forming an amorphous silicon layer on the substrate, carrying out a crystallization process of the amorphous silicon layer to form a layer of polycrystalline silicon defining an active area of the TFT transistor in the layer of polycrystalline silicon; forming a dielectric layer on the active area; forming a gate electrode of the TFT transistor on the dielectric layer; carrying out a single ionic implantation step to realize source/drain regions of the TFT transistor, the ionic implantation step being carried out with a tilt or angled with respect to a normal to a plane defined by the substrate, the tilt angle with respect to the normal to the plane defined by the substrate being comprised in the range of approximately between 7° and 45°. carrying out an activation process of the source/drain regions which does not substantially modify the lateral doping profile of the source/drain regions determined during the implant step.

### PRIORITY CLAIM

This application claims priority from Italian patent application No. MI2006A 001541, filed Aug. 2, 2006, which is incorporated herein by reference.

### TECHNICAL FIELD

An embodiment of the present invention relates to a process for manufacturing a TFT transistor.

More specifically, an embodiment of the invention relates to a process for manufacturing a TFT transistor on a substrate comprising the steps of:

forming an amorphous silicon layer on the substrate;

carrying out a crystallization process of said amorphous silicon layer to form a polycrystalline silicon layer;

defining an active area of the TFT transistor in said polycrystalline silicon layer;

forming a dielectric layer on said active area; and

forming a gate electrode of the TFT transistor on the dielectric layer.

An embodiment of the invention particularly, but not exclusively, relates to a method for manufacturing a TFT transistor and the following description is made with reference to this field of application for convenience of explanation only.

### BACKGROUND

As is known, in the last years, polycrystalline silicon TFT transistors (Thin Film Transistor) have been widely studied and tested relative to their application in SRAM memories and in the display driving circuits with high resolution active matrix, by virtue of their high mobility.

In the document “High-performance polycrystalline-Si thin film transistors formed by using large-angle-tilt implanted drains” by Miin-Horng Juang and Yi-Ming Chiu, published on Semiconductor Science and Technology, 20 (2005) 1223-1225, a process for manufacturing these TFT transistors is described. Examples of final devices realized with this process are shown in FIGS. 1 and 2.

In particular, on a glass substrate 1 an amorphous silicon layer (a-Si) of thickness 100 nm is deposited by means of the LPCVD deposition technique (Low Pressure Chemical Vapor Deposition) at a temperature of 580° C. Subsequently, this amorphous silicon layer is crystallized through exposure to a laser source with xenon chloride (XeCI) with excimers having a wavelength equal to 308 nm for transforming it into a polycrystalline silicon layer 2. Once an active area of these transistors 3, 4 has been defined through a conventional photolithographic technique, on the whole substrate 1, a gate dielectric layer 5 is deposited, for example a TEOS layer being 80 nm thick, by means of the PECVD deposition technique (Plasma Enhanced Chemical Vapor Deposition) at a temperature of 400° C. Then a polysilicon layer being 300 nm thick is deposited. This polysilicon layer is defined to form a gate electrode 6 of length Lch equal to 5 μm. At this point, on the first TFT transistors 3 with structure of the LATID type (Large-Angle-Tilt-Implanted-Drain) a first ionic implantation step is carried out for realizing first lightly doped portions 7 of the source/drain regions, as shown in FIG. 1.

This first ionic implementation step is carried out with a tilt or angled with respect to a normal to a plane defined by the glass substrate. The tilt angle with respect to the normal to the plane defined by the glass substrate is equal to 60°.

In particular, this first ionic implantation is carried out with phosphorus ions with a concentration equal to 6×10¹³ cm⁻² at/cm² and an implant energy of 60 keV.

On second TFT transistors 4 with single S/D structure of the conventional type, a ionic implantation step is instead carried out for realizing source/drain regions 8, as shown in FIG. 2.

In particular, this ionic implantation is carried out with phosphorus ions with a concentration equal to 4×10¹⁵ cm⁻² at/cm² and an implant energy of 100 keV.

The process flow to form the first TFT transistors 3 is completed through deposition of a LTO layer (Low-Temperature-Oxide), which, anisotropically etched, forms spacers 9 on the side walls of the gate electrodes.

The first TFT transistors 3 with structure of the LATID type undergo a second implant step (high dose implant) of phosphorus ions to realize second portions 10 of the source/drain regions of the n+ type, the first regions 7 being shielded by the spacer 9.

In particular, this third ionic implantation is carried out with phosphorus ions with a concentration of 4×10¹⁵ cm⁻² at/cm² and an implant energy of 100 keV.

After an activation process of the phosphorus in oven, at a temperature of 600° C. and for 90 minutes, the devices 3, 4 are passivated by means of a TEOS layer formed through PECVD. The contacts are then defined, by means of deposition and successive selective removal of an aluminium layer. Then the samples undergo a last alloy process at 300° C.

FIG. 3 shows how the dopant concentration profile varies inside the source/drain regions 8 of the second transistors TFT 4 at the end of the implantation process.

With this process, the graduality of the source/drain regions 7, 10 and 8 is modulated by varying the thickness of the layers which form the transistor 3, 4, the architecture of the transistor itself, and the “number” of implants used to form the source/drain regions 7, 10 and 8. That is, to realize a graduality of the lateral doping of these S/D regions, in the prior art process flow a single implant is not enough.

Although advantageous under several aspects, this first technique shows several drawbacks.

In the polysilicon TFT transistors an increase of the leakage current has been observed with the gate and drain voltage in the emptying region next to the drain region, as effect of the charge emission due to the faults in the polycrystalline silicon layer with respect to the transistors of the conventional type. This bias-dependent behavior limits the use of polysilicon TFT transistors as switch elements. In fact, a low on/off time ratio of the TFT transistor limits its performances as switch element in the matrix, jeopardizing the performances of the display itself.

Moreover, it is known that the presence and the integration of structures of the LDD type (Lightly Doped Drain), as those shown in FIG. 1, imply a decrease of the leakage current in the polysilicon TFT transistors due to the reduction of the entity of the electric field next to the drain region. These LDD regions are in fact introduced to increase the graduality of the lateral doping next to the drain region, reducing the charge emission due to the faults.

However, the formation of these LDD regions implies some additional steps in the process flow for the manufacturing of the transistor which may increase the cost of the process.

### SUMMARY

An embodiment of the present invention is a process for forming TFT transistors with source/drain regions of the gradual type, having such characteristics as to overcome problems affecting the processes used in the prior art.

An embodiment of the present invention forms source/drain regions of TFT transistors of the gradual type by means of the single ionic implantation step, wherein only some implant parameters are modified.

An embodiment of the invention comprises the steps of:

carrying out a single ionic implantation step for realizing source/drain regions of the TFT transistor, said ionic implantation step being carried out with a tilt or angled with respect to a normal to a plane defined by said substrate, the tilt angle α with respect to the normal to said plane defined by said substrate being comprised in the range between 7° and 45°.

carrying out an activation process of said source/drain regions, which does not substantially modify the lateral doping profile of the source/drain regions 16 determined during the implant step.

### BRIEF DESCRIPTION OF THE DRAWINGS

Characteristics and the advantages of a device according to one or more embodiments of the invention will be apparent from the following description of an embodiment thereof given by way of indicative and non limiting example with reference to the annexed drawings.

In these drawings:

FIGS. 1 and 2 show vertical section views of TFT transistors formed according to the prior art,

FIG. 3 shows how the dopant concentration profile varies along line II-III of FIG. 2,

FIG. 4 shows a vertical section view of a TFT transistor formed according to a first embodiment of the invention,

FIG. 5 shows how the dopant concentration profiles vary along line V-V of FIG. 4 when the implantation parameters vary according to an embodiment of the invention,

FIG. 5A shows how the dopant concentration profiles vary along line V-V of FIG. 4 when the angulation of the implantation plane varies according to an embodiment of the invention,

FIG. 6 shows a vertical section view of a TFT transistor formed according to a second embodiment of the invention,

FIG. 7 shows how the dopant concentration profiles vary along line VII-VII of FIG. 6 when the profile of the gate electrode varies according to an embodiment of the invention,

FIG. 8 shows how the dopant concentration profiles vary along line V-V of FIG. 4 with a pre-implant dielectric layer present according to an embodiment of the invention,

FIG. 9 shows a vertical section view of a TFT transistor formed according to a third embodiment of the invention,

FIG. 10 shows how the dopant concentration profiles vary along line X-X of FIG. 8 with a pre-implant dielectric layer present according to an embodiment of the invention.

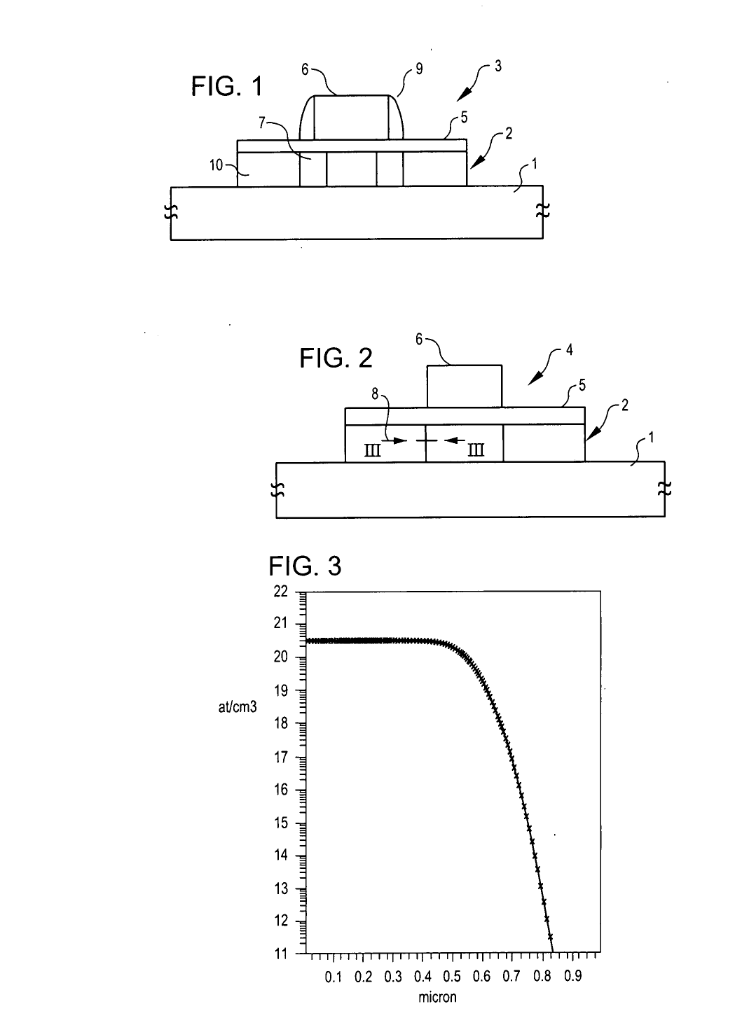

### DETAILED DESCRIPTION

With reference to these figures, a process for manufacturing TFT transistors of the self-aligned type is described according to an embodiment of the invention.

The process steps and the structures described hereafter may not form a complete process flow for the manufacturing of integrated circuits.

The figures showing cross sections of portions of an integrated circuit during the manufacturing may not be drawn to scale, but they are instead drawn so as to show features of one or more embodiments of the invention.

One or more embodiments of the present invention can be put into practice together with the techniques for manufacturing the integrated circuits currently used in the field.

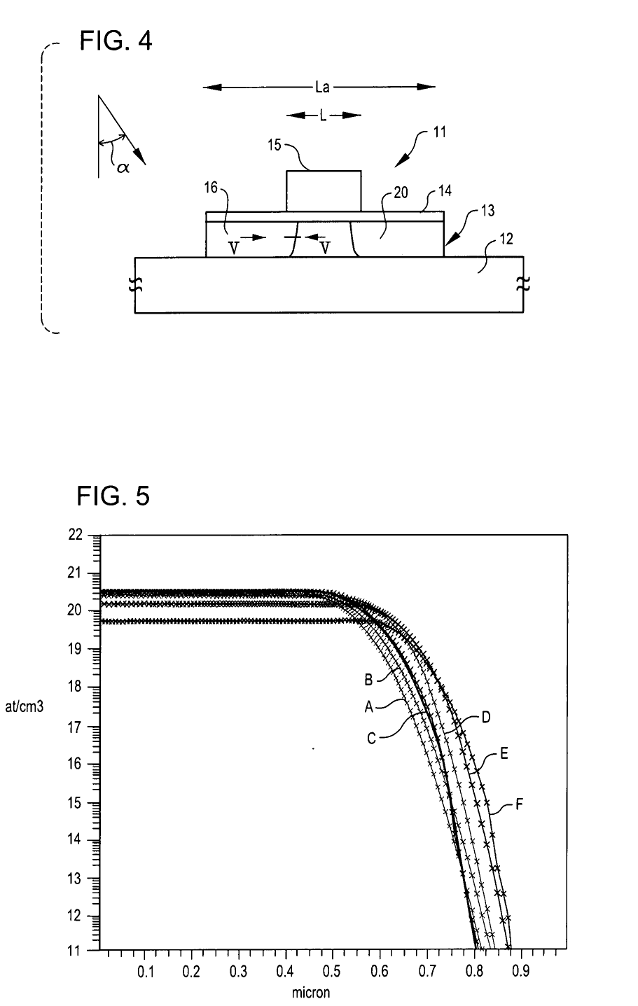

In particular, with reference to FIG. 4, a transistor TFT 11 formed on a substrate 12, for example of glass, is shown according to an embodiment of the invention.

Nothing prevents the substrate 12 from being formed by a plurality of layers, wherein the upper one is an insulating layer.

The substrate 12 may comprise layers of plastic material.

On the layers of plastic material, additional layers may be formed to serve as an interface between the layer of plastic material and the successive polysilicon active layer. In particular, the presence of these additional layers may allow:

solving possible adhesion problems between the polysilicon layer and the plastic layer, and

protecting the plastic layer from the successive laser irradiation step and the consequent heat development which could damage this plastic layer.

These additional layers may be dielectric layers.

On the substrate 12, an amorphous silicon layer is formed which, as described with reference to the prior art, undergoes a crystallization process to form a polycrystalline silicon layer 13.

The thickness of this polycrystalline silicon layer 13 may be equal to 100 nm if integrated in conventional manufacturing processes. In fact, the current conventional manufacturing processes often do not ensure the formation of polysilicon layers of uniform thickness lower than 100 nm.

The thickness of this polycrystalline silicon layer 13 may be lower than 100 nm to reduce the turn-off current (off) of the transistor 11 according to an embodiment of the invention.

An active area of the TFT transistor 11 is then defined, for example of length La equal to 15 μm and width Wa equal to at least 5 μm, which will take the shape of a substantially rectangular island formed on the substrate 12.

On the polycrystalline silicon layer 13, a dielectric layer 14 is formed, for example, of silicon oxide.

The thickness of this dielectric layer 14 may be between 80 and 150 nm, for example 80 nm.

In particular, the thickness of this dielectric layer 14 may be chosen on the basis of the design threshold value of the transistor 11.

On the dielectric layer 14, a conductive layer is then formed for realizing a gate electrode 15 of the TFT transistor 11 of length L and width W.

For example, the length L is equal to 5 μm and the width W is equal to that (Wa) of the active area such that it is of at least 5 μm.

In particular, when the width Wa of the active area and thus of the width W of the transistor 11 increases according to an embodiment of the invention, the current through the transistor 11 can sustain increases.

For example, the gate electrode 15 may be formed by a polysilicon layer.

Or, the gate electrode 15 may be formed by a metallic layer.

A removal step is carried out of the portion of the dielectric layer 14 not covered by the gate electrode 15.

According to an embodiment of the invention, a single ionic implantation step is carried out for realizing a source/drain region 16 of the TFT transistor 11.

According to an embodiment of the invention, this ionic implantation step is carried out with a tilt or angled with respect to a normal to a plane defined by the substrate 11. The tilt angle α with respect to the normal to the plane defined by the substrate 11 is comprised between approximately 7° and 45°, for example between approximately 7° and 30°.

In particular, this ionic implementation is carried out with ions of the n type with a concentration comprised between approximately 5×10¹⁴ cm⁻² and 5×10¹⁵ cm⁻², for example equal to 4×10¹⁵ cm⁻² at/cm².

According to an embodiment of the invention, it is possible to increase the amount of implanted dopant on the basis of the activation type which will be subsequently carried out in the process according to an embodiment of the invention, as it will be hereafter described.

According to an embodiment of the invention, the implant energy depends on the thickness of the dielectric layer 14 through which the implantation step occurs, as well as on the type of the implanted dopant type.

In particular, for a dielectric layer 14 formed by an oxide layer of 80 nm, the implant energy is, for example, equal to 100 keV.

A further source/drain region 20 of the TFT transistor 11, positioned on the opposite part of the gate electrode with respect to the first source/drain region 16, is formed by carrying out a further ionic implantation step carried out with a tilt or angled with respect to a normal to a plane defined by the substrate 11. The tilt angle α with respect to the normal to the plane defined by the substrate 11 is comprised between approximately −7° and −45°, for example between approximately −7° and −30°, the negative sign indicating that the tilt angle of this latter implantation step is on the opposite part of the normal with respect to the tilt angle of the previous ionic implantation step.

The source/drain regions 16 and 20 may then undergo an activation process which does not substantially modify the lateral doping profile of the source/drain regions 16 and 20 determined during the implant step.

The activation process may occur at low temperature, for example lower than 300° C., allowing the integration on substrates 12 of the plastic type.

Said activation step may be carried out through exposure to a laser source, for example a excimers, which carries out the activation step by acting superficially in the TFT transistor 11 and also carries out a recovery of the structure of the polysilicon layer 13 which may be, as known, damaged during the implantation step.

Therefore, by providing an activation step through exposure to a laser source, it may be possible to implant a greater amount of dopant with respect to the transistors activated by means of thermal processes which occur in an oven at the same temperatures, the crystalline structure of the polysilicon layer 13 being recovered in this activation step.

Moreover, by carrying out an activation step which acts superficially in the TFT transistor 11, according to an embodiment of the invention, it may be possible to use non conventional substrates, comprising plastic material layers suitably shielded, which cannot undergo treatments in oven which would deteriorate the structure.

With the method according to an embodiment of the invention, with the single implantation step, the decrease of the doping of the source/drain regions 16 and 20 is made less quick, i.e. more gradual, below the gate electrode 15. Thus, source/drain regions 16 and 20 are realized having a greater lateral extension with respect to the conventional TFT transistors, allowing an improvement of the performances of the TFT transistor 11 in terms of reduction of the leakage current.

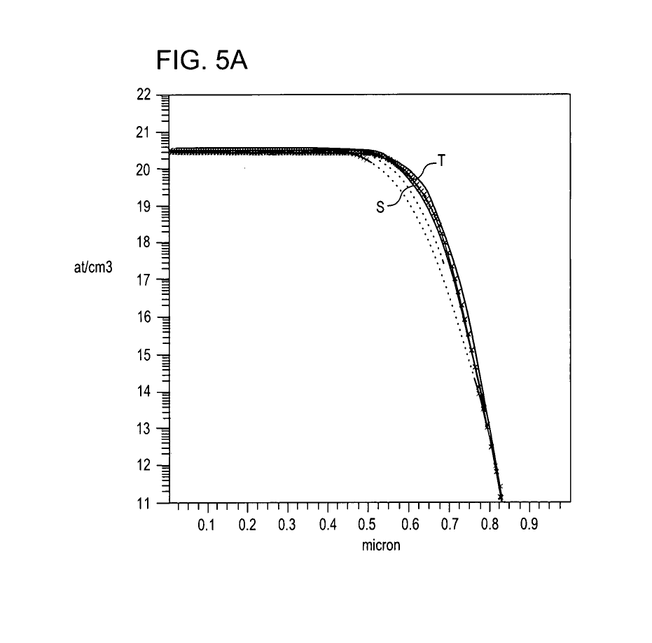

FIG. 5 indicates the dopant concentration profiles inside the source/drain regions 16 and 20 when the tilt angle α with which the ionic implantation step of these regions 16 and 20 is carried out varies. In particular, the curve A shows the concentration profile when the tilt angle α is equal to the curve B shows the concentration profile when the tilt angle α is equal to 7° (and −7° for the region 20), the curve C shows the concentration profile when the tilt angle α is equal to 15° (and −15°), the curve D shows the concentration profile when the tilt angle α is equal to 30° (and −30°), the curve E shows the concentration profile when the tilt angle α is equal to 45° (and −45°) and the curve F shows the concentration profile when the tilt angle α is equal to 60° (and −60°).

The progress of these curves confirms that if the tilt angle α is comprised between 7° (−7°) and 30° (−30°), the concentration of the source/drain regions 16 and 20 below the gate electrode 15 is likely to decrease more gradually with respect to the source/drain regions 16 and 20 formed with the tilt angle α equal to 0°.

Source/drain regions 16 and 20 formed instead with the tilt angle α higher than 30° (−30°), although having an even more gradual profile with respect to those realized when the tilt angle α is comprised between 7° (−7°) and 30° (−30°), may not ensure a sufficiently high dopant concentration inside the source/drain regions 16 and 20, implying a degradation of the performances of the TFT transistor 11.

According to an embodiment of the invention, a further lateral extension of the source/drain regions 16 and 20 below the gate electrode 15 may be obtained by modifying the angle of the implantation plane with respect to a plane passing through the normal to the substrate, for the gate electrode 15 and the source/drain regions 16 and 20, where the implantation plane is the plane determined by the normal to the substrate 12 and the direction of the implanted ions beam.

The angle comprised between these two planes defines the twist angle. According to an embodiment of the invention, the twist angle is comprised between approximately 0° and 27°. In particular, when the twist angle is equal to zero the maximum extension is obtained, as it can be noted from FIG. 5A, where the dopant concentration profiles inside the source/drain regions 16 and 20 when the twist angle varies are indicated. In particular, the curve S shows the concentration profile when the implantation step is carried out with a twist angle equal to 20° and a tilt angle α equal to 25° (−25°) while the curve T, wider, shows the concentration profiles of the source/drain regions 16 and 20 when the tilt angle α is always equal to 20° (−20°) with a twist angle equal to 0°.

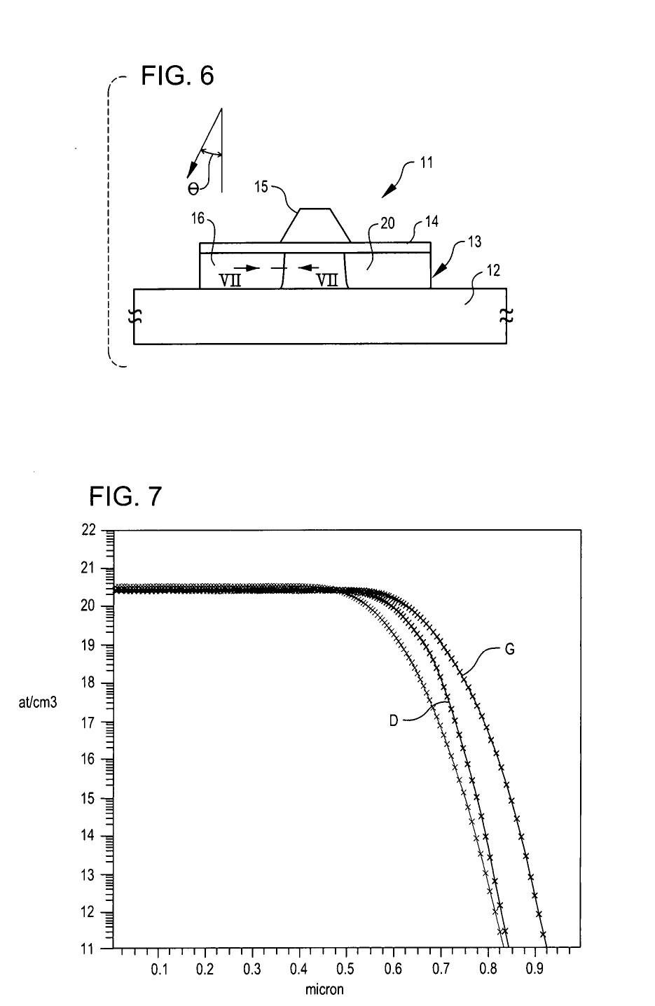

With reference to FIG. 6, a TFT transistor 11 is shown being realized according to a second embodiment of the invention. Elements being structurally and functionally identical with respect to the TFT transistor described with reference to FIG. 4 will be given the same reference numbers.

In particular, a TFT transistor 11 is formed on a substrate 12.

On the substrate 12 an amorphous silicon layer is formed which, as described with reference to the prior art, undergoes a crystallization process to form a polycrystalline silicon layer 13.

After having defined an active area of the TFT transistor 11, a dielectric layer 14 is formed, for example silicon oxide, on the polycrystalline silicon layer 13.

On the dielectric layer 14, a conductive layer is then formed to realize a gate electrode 15 of the TFT transistor 11 of length L.

The gate electrode 15 may be formed by a metallic layer.

According to an embodiment of the invention, a shaping step of the profile of the gate electrode 15 is then carried out by means of an etching step carried out with a tilt or angled with respect to a normal to a plane defined by the substrate 12. After this shaping step the gate electrode 15 is then flared, i.e., the dimensions of the cross sections of the gate electrode 15 decrease as one moves away from the substrate 12.

The tilt angle θ with respect to the normal to the plane defined by the substrate 12 varies in a range between −30° (30°) and −60° (60°) and for example is equal to −45° (45°), the negative sign indicating that the tilt angle of this etching step is on the opposite side of the normal to the tilt angle α of the successive ionic implantation step.

The etching step of the layer forming the gate electrode may be of the non anisotropic type, and thus may be simpler, less “delicate”, and thus with lower cost with respect to a step of the anisotropic type for realizing a vertical profile of the gate electrode.

According to an embodiment of the invention, this shaping step may be carried out whether the gate electrode is formed by a polysilicon layer or by a metallic layer.

A single ionic implantation step is then carried out to realize a source/drain region 16 of the TFT transistor 11 with, for example, the modes indicated in the previous embodiment.

By carrying out this shaping step, i.e. flaring, of the gate electrode 15 it may be possible to obtain, according to an embodiment of the invention, a further lateral extension of the source/drain regions 16 below the gate electrode 15 itself.

A further ionic implantation step is then carried out to realize the other source/drain region 20 of the TFT transistor 11 with, for example, the same modes indicated in the previous embodiment.

In FIG. 7, the curve G shows the dopant concentration profile inside the source/drain regions 16 and 20 in this latter embodiment, which is wider with respect to the concentration profile of the source/drain regions 16 and 20 under the same implant conditions, when the gate electrode 15 is not flared. This latter profile is shown by the curve D reported in the same figure.

In a further embodiment of the invention, before carrying out the implantation step to form the source/drain region 16, a removal step is carried out of the portion of the dielectric layer 14 not covered by the gate electrode 15, which is followed by a formation step of a pre-implant dielectric layer, for example of silicon oxide.

The thickness of this pre-implant dielectric layer may be between 80 nm and 130 nm.

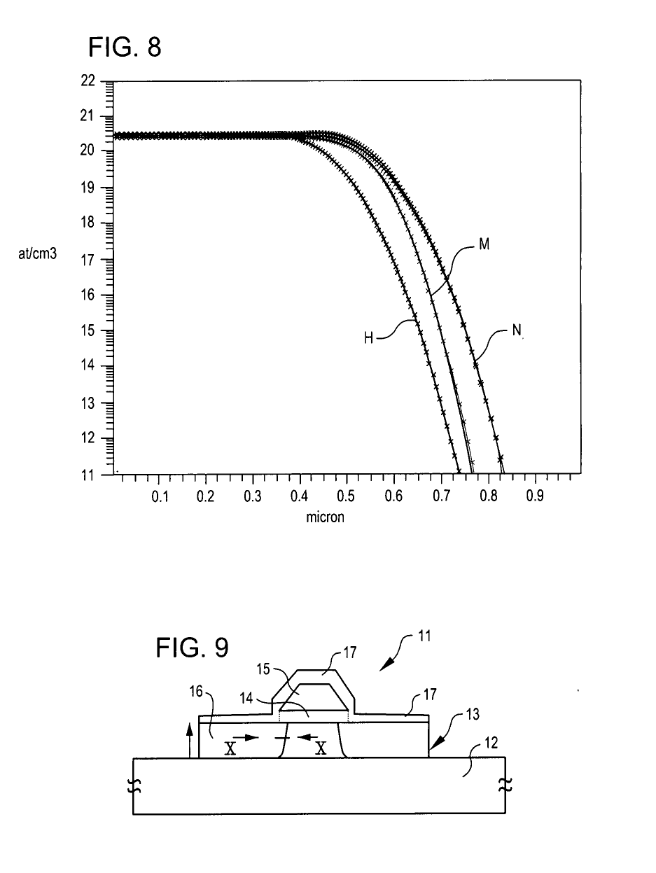

The presence of the pre-implant dielectric layer is a shield for the successive implantation step, and may cause a reduction of the lateral extension of the source/drain region 16 below the gate electrode 15 itself, as shown in FIG. 8, wherein the curve H shows the dopant concentration profile inside the source/drain regions 16 and 20 when the pre-implant dielectric layer with a thickness of 80 nm is formed on the gate electrode 15, where the tilt angle α with which the source/drain regions 16 and 20 are formed is equal to 7° (−7°), while the curve M shows the dopant concentration profile inside the source/drain regions 16 and 20 when the pre-implant dielectric layer with a thickness of 80 nm is formed on the gate electrode 15, where the tilt angle α with which the source/drain regions 16 and 20 are formed is equal to 30° (−30°).

To increase the lateral extension of the source/drain regions 16 and 20 below the gate electrode 15 itself, according to an embodiment of the invention, a flaring of the gate electrode 15 is carried out according to a second embodiment of the invention.

FIG. 8 also reports the curve N showing the dopant concentration profile inside the source/drain regions 16 and 20 when the pre-implant dielectric layer with a thickness of 80 nm is formed on the gate electrode 15 of the flared type, wherein the tilt angle α of the implantation step with which the source/drain regions 16 and 20 are formed is equal to 30° (−30°). The flaring of the gate electrode 15 then allows an increase in the lateral extension of the source/drain regions 16.

A TFT transistor realized according to this latter embodiment is shown in FIG. 9, wherein the pre-implant dielectric layer is indicated with reference number 17.

If the thickness of the pre-implant dielectric layer 17 is greater than the thickness of the dielectric layer 14, by modifying, according to an embodiment of the invention, the tilt angle α of the implantation step and the lateral profile of the gate electrode, it may be possible to increase the lateral extension of the source/drain regions 16 and 20 maintaining their dopant concentration constant there inside, by increasing the implant energy with which these regions are realized.

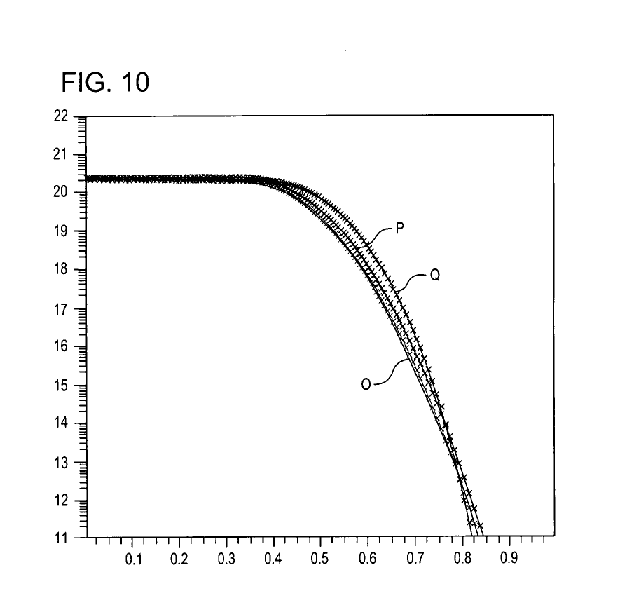

In FIG. 10, instead, the curve 0 shows the dopant concentration profile inside the source/drain regions 16 and 20 of the transistor 11 of FIG. 9 when the pre-implant dielectric layer 17 has a thickness of 130 nm, wherein the tilt angle α of the implantation step with which the source/drain regions 16 and 20 are formed is equal to 0°, the curve P shows the dopant concentration profile inside the source/drain regions 16 of the transistor 11 of FIG. 9 when the pre-implant dielectric layer 17 has a thickness of 130 nm, wherein the tilt angle α of the implantation step with which the source/drain regions 16 are formed is equal to 7° (−7°), while the curve Q shows the dopant concentration profile inside the source/drain regions 16 of the transistor 11 of FIG. 9 when the pre-implant dielectric layer 17 has a thickness of 130 nm, wherein the tilt angle α of the implantation step with which the source/drain regions 16 and 20 are formed is equal to 20° (−20°).

However, as it can be noted form the figures, the tilt angle α effect may be less but still present, when the thickness of the pre-implant dielectric layer 17 increases.

The concentration profiles reported in FIGS. 5, 7, 8 and 10 have been calculated, by mere way of example, for a TFT transistor 11 comprising a polysilicon layer 13 of thickness equal to 100 nm, a TEOS insulating layer 14 of thickness equal to 80 nm, a gate electrode 15 of width equal to 5 μm and of thickness equal to 300 nm. The source/drain regions 16 and 20 have been formed by an ionic implantation carried out with ions of the n type with a concentration of 4×10¹⁵ cm⁻² at/cm² and an implant energy of 100 keV.

In conclusion, a process according to an embodiment of the invention may attain the following:

the lateral extension of the source/drain regions 16 and 20, and then the modulation of the lateral doping of these source/drain regions 16 and 20, is realized with a single high dose implant;

does not include any additional process step with respect to the conventional manufacturing processes suitably combining the values of implant parameters (tilt and twist angle) and the etching angle of the gate electrode for flaring this electrode, so as to minimize the high electric field effects at the edge of the drain region and then next to the channel region which implies, as known, a potential accelerated deterioration of the electric performances of the TFT transistor;

allows to vary, i.e. modulate, according the design needs and in a controlled way, the gradient of the dopant profile of the source/drain regions during the implantation step, the successive activation step substantially not affecting the extension of this dopant profile;

allows to reduce, in a controlled way, the dimensions of the length of the effective channel region and to compact then the space area of the TFT transistors to the advantage of applications with better electric performances, realizing a dedicated graduality of the lateral doping of the source/drain regions by implantation;

allows to form the gate electrode by means of a metallic layer by adding one more metallization level (gate metal) to the conventional process flow;

it is possible to modulate the dopant profile in the implant step in a dedicated way for both the transistors of the n and p type, even with a metallic gate electrode for both the types of components;

providing, in the process flow, also the formation of a pre-implant dielectric layer, the implantation step of the source/drain regions can be easily repeated, this new layer having a constant thickness while the insulating layer formed before the gate electrode protecting the source/drain regions could get damaged during the successive formation step of the gate electrode causing undesired modifications to the profile of the source/drain regions;

succeeds in integrating a gate dielectric layer different from the TEOS for needs of process flow (for example by integrating an insulating layer with etching selectivity with respect to the polysilicon different from that of the silicon oxide (SiO₂), so as to solve the drawback of the over-etch of the already thin polysilicon layer 13 which is defined by means of an anisotropic definition (for example in dry) of the gate electrode or, from an electric viewpoint, being the thickness of the insulating layer 14 identical below the gate electrode 15, so as to decrease the value of the threshold voltage of the TFT transistor 11, also being a suitable intermediate layer present between the polysilicon layer 13 and this insulating layer 14 so as to optimize the interface;

according to an embodiment of the invention, a lateral modulation of the dopant occurs through the specifications of the same (single) doping process through implantation according to a range (lateral) which, for example not higher than 50 nm, constitutes the 50% of the thickness of the polysilicon active layer 13 of the TFT transistor (100 nm);

not tied to a type of substrate, since it can be integrated in any type of poly-TFT technology, also on plastic substrate. In fact, the activation process through laser irradiation may be superficial with respect to the plastic substrate.

A TFT made and/or structured according to an embodiment of the invention may be disposed in an IC or in a display, and such IC or display may form part of an electronic system such as a television set.

From the foregoing it will be appreciated that, although specific embodiments of the invention have been described herein for purposes of illustration, various modifications may be made without deviating from the spirit and scope of the invention.

1. Process for manufacturing a TFT transistor on a substrate comprising the steps of:
forming an amorphous silicon layer on the substrate,
carrying out a crystallization process of said amorphous silicon layer to form a layer of polycrystalline silicon;
defining an active area of the TFT transistor in said layer of polycrystalline silicon;
forming a dielectric layer on said active area;
forming a gate electrode of the TFT transistor on the dielectric layer;
carrying out a single ionic implantation step to realize source/drain regions of the TFT transistor, said ionic implantation step being carried out with a tilt or angled with respect to a normal to a plane defined by said substrate, the tilt angle with respect to the normal to said plane defined by said substrate being comprised in the range of approximately between 7° and 45°;
carrying out an activation process of said source/drain regions which does not substantially modify the lateral doping profile of said source/drain regions determined during the implant step.

2. Process for manufacturing a TFT transistor according to claim 1, wherein said tilt angle is comprised in the range between 7° and 30°.

3. Process for manufacturing a TFT transistor according to claim 1, wherein before carrying out said implantation step, a shaping step of the lateral profile of said gate electrode is carried out, by means of an etching step carried out with a tilt or angled with respect to a normal to a plane defined by the substrate, so that the gate electrode is then flared such that the dimensions of the cross sections of the gate electrode decrease departing from the substrate.

4. Process for manufacturing a TFT transistor according to claim 3, wherein said shaping step is carried out with a tilt angle with respect to the normal to the plane defined by the substrate which varies in a range between −30° and −60.

5. Process for manufacturing a TFT transistor according to claim 3, wherein immediately after the shaping step, the process comprises the further steps of:
removing said dielectric layer, not covered by said gate electrode,
formation of a pre-implant dielectric layer.

6. Process for manufacturing a TFT transistor according to claim 3, wherein said pre-implant dielectric layer comprises a silicon oxide layer.

7. Process for manufacturing a TFT transistor according to claim 1, wherein said substrate comprises a glass layer.

8. Process for manufacturing a TFT transistor according to claim 1, wherein said substrate comprises a layer of plastic material.

9. Process for manufacturing a TFT transistor according to claim 1, wherein said gate electrode is formed by a polysilicon layer.

10. Process for manufacturing a TFT transistor according to claim 1, wherein said gate electrode is formed by a metallic layer.

11. Process for manufacturing a TFT transistor according to claim 1, wherein said ionic implantation step is carried out with ions of the n type with a concentration comprised between 5×10¹⁴ cm⁻² and 5×10¹⁵ cm⁻², preferably equal to 4×10¹⁵ cm⁻² at/cm².

12. Process for manufacturing a TFT transistor according to claim 8, wherein said activation step is carried out at a temperature lower than 300°.

13. Process for manufacturing a TFT transistor according to claim 1, wherein said activation step is carried out through exposure to a laser source.

14. Process for manufacturing a TFT transistor according to claim 1, wherein said shaping step is carried out through an etching step of the non anisotropic type.

15. Process for manufacturing a TFT transistor according to claim 1, wherein immediately after the shaping step, the process comprises the step of:
removing said dielectric layer, not covered by said gate electrode.

16. Process for manufacturing a TFT transistor according to claim 1, wherein the angle comprised between the implantation plane and a plane passing through said normal to said substrate, through said gate electrode and said source/drain regions is comprised in a range between 0° and 27°.

17. Process for manufacturing a TFT transistor according to claim 1, wherein said polycrystalline silicon layer has a thickness lower or equal to 100 nm.

18. Process for manufacturing a TFT transistor according to claim 1, wherein said dielectric layer is a silicon oxide layer whose thickness is between 80 nm and 150 nm.

19. Process for manufacturing a TFT transistor according to claim 5, wherein said pre-implant dielectric layer has the same thickness as said dielectric layer.

20. Process for manufacturing a TFT transistor according to claim 5, wherein said pre-implant dielectric layer has a greater thickness than said dielectric layer.

21. A method, comprising:
implanting into a region of a semiconductor layer having a surface a dopant at an acute first angle relative to the surface such that the implanted dopant has a concentration profile in a dimension; and
activating the implanted dopant without substantially changing the concentration profile.

22. The method of claim 21 wherein the semiconductor layer is disposed on an insulator.

23. The method of claim 21 wherein the implanting comprises varying the angle while implanting the dopant.

24. The method of claim 21 wherein a portion of the region overlaps an edge of a layer that is disposed over the semiconductor layer.

25. The method of claim 21 wherein activating the implanted dopant comprises activating the implanted dopant with electromagnetic energy.

26. The method of claim 21 wherein activating the implanted dopant comprises activating the implanted dopant with a laser beam.

27. The method of claim 21 wherein the implanting comprises implanting the dopant through a layer that is disposed over the semiconductor layer.

28. The method of claim 21 wherein the implanting comprises implanting the dopant at a second angle that is orthogonal to the first angle.

29. The method of claim 21 wherein the implanting comprises:
implanting the dopant at a second angle that is orthogonal to the first angle; and
varying the second angle while implanting the dopant.

30. The method of claim 21 wherein the region of the semiconductor layer comprises a source/drain region.

31. A method, comprising:
implanting a dopant through a first layer and into a region of a semiconductor second layer, the first layer having an edge and having a first surface lying substantially in a first plane, the second layer having a second surface lying substantially in a second plane that makes an acute first angle with the first plane, the region overlapping the edge of the first layer; and
activating the implanted dopant.

32. The method of claim 31, further comprising forming the first surface of the first layer before implanting the dopant.

33. The method of claim 31, further comprising forming a third layer over the first and second layers before implanting the dopant.

34. The method of claim 31 wherein the implanting comprises implanting the dopant at an acute second angle relative to the second plane.

35. The method of claim 31 wherein the implanting comprises:
implanting the dopant at an acute second angle relative to the second plane; and
varying the second angle while implanting the dopant.

36. The method of claim 31 wherein:
the implanting comprises implanting the dopant such that the implanted dopant has a concentration profile in a dimension; and
the activating comprises activating the implanted dopant without substantially changing the concentration profile.

37. The method of claim 1 wherein the implanting comprises implanting the dopant through a layer that is disposed over the semiconductor layer.

38. The method of claim 31 wherein the implanting comprises implanting the dopant at an acute second angle relative to the second plane, and at a third angle that is orthogonal to the second angle.

39. A transistor, comprising:
a semiconductor layer having a first surface;
source/drain regions disposed in the semiconductor layer; and
a gate disposed over the semiconductor layer and having a second surface that is acutely angled relative to the first surface.

40. The transistor of claim 39, further comprising:
an insulator substrate; and
wherein the semiconductor layer is disposed over the substrate.

41. The transistor of claim 39 wherein:
the gate has an edge; and
a portion of the gate has a height that increases with distance from the edge.

42. The transistor of claim 39 wherein:
the gate has an edge and a center; and
the second surface slopes toward the first surface and the edge and away from the center.

43. An integrated circuit, comprising:
a transistor, including
a semiconductor layer having a first surface,
source/drain regions disposed in the semiconductor layer, and
a gate disposed over the semiconductor layer and having a second surface that is acutely angled relative to the first surface.

44. A system, comprising:
a first integrated circuit, comprising
a transistor, including
a semiconductor layer having a first surface,
source/drain regions disposed in the semiconductor layer, and
a gate disposed over the semiconductor layer and having a second surface that is acutely angled relative to the first surface; and
a second integrated circuit coupled to the first integrated circuit.

45. The system of claim 44 wherein the first and second integrated circuits are disposed on a same die.

46. The system of claim 44 wherein the first and second integrated circuits are disposed on respective dies.

47. The system of claim 44 wherein the second integrated circuit comprises a controller.

48. The system of claim 44 wherein the first integrated circuit comprises an image display.
